(19) United States
(12) Patent Application Publication
(10) Pub. No.: US 2024/0047292 A1
(43) Pub. Date: Feb. 8, 2024

(54) SEMICONDUCTOR PACKAGE

(71) Applicant: SAMSUNG ELECTRONICS CO., LTD., Suwon-si (KR)

(72) Inventor: Su Jung HYUNG, Suwon-si (KR)

(73) Assignee: SAMSUNG ELECTRONICS CO., LTD., Suwon-si (KR)

(21) Appl. No.: 18/140,343

(22) Filed: Apr. 27, 2023

(30) Foreign Application Priority Data
Aug. 8, 2022 (KR) 10-2022-0098672

(51) Int. Cl. H01L 23/367; H01L 23/31; H01L 23/00; H01L 23/498; H01L 23/373; H01L 25/065

(52) U.S. Cl. CPC H01L 23/367; H01L 23/3157; H01L 24/16; H01L 23/49816; H01L 24/32; H01L 24/73; H01L 23/3737; H01L 25/0655; H01L 2224/16225; H01L 2224/32221; H01L 2224/73253

(57) ABSTRACT

A semiconductor package includes a substrate, at least one semiconductor chip provided on an upper surface of the substrate, a molding layer provided on a portion of a sidewall of the at least one semiconductor chip, and a heat dissipation member comprising at least one trench that contacts an upper surface of the at least one semiconductor chip and another portion of the sidewall of the at least one semiconductor chip.

### CROSS-REFERENCE TO RELATED APPLICATION

This application claims priority to Korean Patent Application No. 10-2022-0098672, filed on Aug. 8, 2022, in the Korean Intellectual Property Office, the disclosure of which is incorporated herein by reference in its entirety.

### BACKGROUND

### 1. Field

The present disclosure relates to a semiconductor package.

### 2. Description of Related Art

Semiconductor packaging is a process of packaging a semiconductor chip to electrically connect a semiconductor chip (or semiconductor die) with an electronic device.

Recently, as implementation of high performance devices is required, a size of a semiconductor chip is increased and a size of a semiconductor package is correspondingly increased. On the other hand, a thickness of the semiconductor package is reduced in accordance with the slimness tendency of the electronic device.

In particular, while various semiconductor chips are provided, heat of a high temperature may be generated in the semiconductor chips during operation. When such heat of a high temperature is transferred to a semiconductor chip for performing a memory function, performance degradation, such as destruction of a memory cell and an error operation, may be caused.

### SUMMARY

Provided is a semiconductor package that may improve heat emission efficiency while supplementing its size based on increase in a size of a semiconductor chip.

According to an aspect of an example embodiment, a semiconductor package may include a substrate, at least one semiconductor chip provided on an upper surface of the substrate, a molding layer provided on a portion of sidewall of the at least one semiconductor chip, and a heat dissipation member comprising at least one trench that contacts an upper surface of the at least one semiconductor chip and another portion of the sidewall of the at least one semiconductor chip.

According to an aspect of an example embodiment, a semiconductor package may include a substrate, at least two semiconductor chips provided on an upper surface of the substrate, a molding layer provided on the upper surface of the substrate and first portions of sidewalls of the at least two semiconductor chips, and a heat dissipation member including a first trench engaged with an upper portion and upper sidewalls of a first semiconductor chip of the at least two semiconductor chips, and a second trench engaged with an upper portion and upper sidewalls of a second semiconductor chip of the at least two semiconductor chips, where the heat dissipation member is provided on an upper edge of the substrate, an upper portion and a sidewall of the molding layer, an upper surface of each of the at least two semiconductor chips, and second portions of the sidewalls of the at least two semiconductor chips.

According to an aspect of an example embodiment, a semiconductor package may include a substrate, at least two semiconductor chips provided on an upper surface of the substrate, a molding layer provided on the upper surface of the substrate and a portion of sidewalls of the at least two semiconductor chips, a dummy heat dissipation plate provided on an upper surface of each of the at least two semiconductor chips, a thermal interface material (TIM) provided on the dummy heat dissipation plate, and a heat dissipation member provided on upper sidewalls of the at least two semiconductor chips, at least a portion of the dummy heat dissipation plate and at least a portion of the TIM, where the heat dissipation member contacts at least one of the upper sidewalls of the at least two semiconductor chips.

### BRIEF DESCRIPTION OF THE DRAWINGS

The above and other aspects, features, and advantages of certain example embodiments of the present disclosure will be more apparent from the following description taken in conjunction with the accompanying drawings, in which:

FIGS. 1A and 1B are cross-sectional views illustrating a semiconductor package according to the an example embodiment of the present disclosure;

FIG. 2 is a cross-sectional view illustrating a semiconductor package according to an example embodiment of the present disclosure;

FIGS. 3, 4, 5, 6 and 7 are diagrams illustrating a method of manufacturing a semiconductor package according to an example embodiment of the present disclosure;

FIG. 8 is a cross-sectional view illustrating a semiconductor package according to an example embodiment of the present disclosure;

FIGS. 9, 10, 11, 12 and 13 are diagrams illustrating a method of manufacturing a semiconductor package according to an example embodiment of the present disclosure;

FIG. 14 is a cross-sectional view illustrating a semiconductor package according to an example embodiment of the present disclosure; and

FIGS. 15, 16, 17, 18, 19 and 20 are diagrams illustrating a method of manufacturing a semiconductor package according to an example embodiment of the present disclosure.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms

It will be understood that although the terms such as first, second, etc. may be used herein to describe various elements, these elements should not be limited by these terms. These terms are generally only used to distinguish one element from another element. Also, in the description of the present disclosure, when the detailed description of the relevant known art is determined to unnecessarily obscure the subject matter of the present disclosure, the detailed description will be omitted.

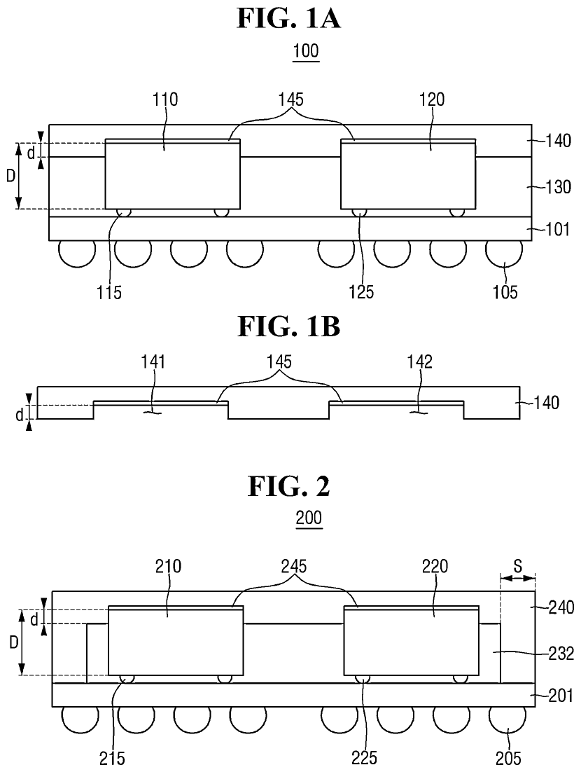

FIGS. 1A and 1B are a cross-sectional views illustrating a semiconductor package according to an example embodiment of the present disclosure.

A semiconductor package 100 according to an example embodiment of the present disclosure may include a substrate 101, two semiconductor chips including a first semiconductor chip 110 and a second semiconductor chip 120 packaged on an upper surface of the substrate 101, a molding layer 130 formed to cover a portion of the upper surface of the substrate 101 and sidewalls of the semiconductor chips 110 and 120, and a heat dissipation member 140 attached to an upper surface and an upper portion of the sidewalls of the semiconductor chip 110 and 120 with a thermal interface material (TIM) 145 interposed therebetween. In addition, the semiconductor package 100 according to an example embodiment of the present disclosure may further include bumps 115 and 125 connecting the substrate 101 with the semiconductor chips 110 and 120, and solder balls 105 attached to a lower surface of the substrate 101.

The substrate 101 may be, for example, a printed circuit board (PCB). The PCB may be a single-sided PCB or a double-sided PCB, and may be a multi-layer PCB that includes one or more internal wiring patterns inside the substrate. In addition, the substrate 101 may be a rigid-PCB or a flexible-PCB.

Such a substrate 101 may include, for example, an epoxy resin, a polyimide resin, a bismaleimide triazine (BT) resin, a flame retardant 4 (FR-4), FR-5, ceramic, silicon, glass, photosensitive liquid dielectrics, photosensitive dry-film dielectrics, polyimide flexible film thermally cured dry films, thermally cured liquid dielectrics, resin coated copper foil (RCC), a thermoplastic, or a flexible resin.

In addition, the substrate 101 may be formed by bonding a plurality of rigid plates, or may be formed by bonding a thin flexible PCB (FPCB) to a rigid flat plate. The plurality of rigid plates or PCBs, which are bonded to each other, may include wiring patterns, respectively. In addition, the substrate 101 may include a low temperature co-fired ceramic (LTCC) substrate. The LTCC substrate may include a plurality of ceramic layers that are stacked, and may include a wiring pattern inside the ceramic layers.

The substrate 101 may include at least one insulating layer and a metal wiring layer. The metal wiring layer is a circuit pattern formed on the substrate 101, and may be formed of, for example, aluminum (Al) or copper (Cu). A surface of the metal wiring layer may be plated with tin (Sb), gold (Au), nickel (Ni), or lead (Pb).

The substrate 101 may also include a conductive pad for connecting the semiconductor chips 110 and 120 with the substrate 101 via the bump 115, and a solder ball pad on which the solder ball 105 for connecting the semiconductor package 100 with an external circuit is positioned. The conductive pad and the solder ball pad may be formed of, for example, aluminum (Al) or copper (Cu). A surface of each of the conductive pad and the solder ball pad may be plated with, for example, tin (Sb), gold (Au), nickel (Ni) or lead (Pb). Each of the conductive pad and the solder ball pad may be a portion of the metal wiring layer.

The substrate 101 may further include a via structure, such as a through silicon via (TSV), which connects the conductive pad with the solder ball pad by passing through an upper surface and a lower surface of at least a portion of the substrate 101.

As shown in FIG. 1A, the semiconductor chips may include a first semiconductor chip 110 packaged on one side of the upper surface of the substrate 101 and a second semiconductor chip 120 packaged on the other side of the upper surface of the substrate 101. One semiconductor chip or multiple semiconductor chips may be packaged on the upper surface of the substrate 101 without limitation to the structure in which two semiconductor chips 110 and 120 are packaged on the upper surface of the substrate 101.

The semiconductor chips 110 and 120 may be packaged on the substrate 101 in a flip-chip bonding method or in a wire bonding method, but this is only an example and embodiments of the disclosure are not limited thereto.

When the semiconductor chips 110 and 120 are packaged in a flip-chip bonding method, the semiconductor chips 110 and 120 may be connected to the substrate 101 through the bumps 115 and 125, respectively, and an active surface of the semiconductor chips 110 and 120 may be attached toward the substrate 101.

The semiconductor chips 110 and 120 may be semiconductor chips configured to perform various functions, such as memories, logics, microprocessors, analog devices, digital signal processors, and system-on-chips. In addition, the semiconductor chips 110 and 120 may be multi-chips having a structure in which at least two semiconductor chips are stacked. In particular, both the first semiconductor chip 110 and the second semiconductor chip 120 may be the same type of memory devices, or one may be a memory device and the other one may be a micro-controller device.

The molding layer 130 may be formed to cover (or cover at least a portion of) the upper surface of the substrate 101 and a portion of the sidewalls of the semiconductor chips 110 and 120. The molding layer 130 may be formed to cover (or cover at least a portion of) a sidewall region excluding a predetermined heat dissipation trench depth of the trenches (e.g., trenches 141 and 142 described below) with respect to a sidewall height ‘D’ of the semiconductor chips 110 and 120. The predetermined heat dissipation trench depth ‘d’ may be set up to about 50% of the sidewall height ‘D’.

The molding layer 130 may be formed by, for example, a molded under fill (MUF) process. The MUF process may refer to a process in which a space between the semiconductor chips 110 and 120 and the substrate 101 is filled with the molding layer 130 without a separate process of filling the space between the semiconductor chips 110 and 120 and the substrate 101 with an under fill.

The molding layer 130 may be formed by a process other than the MUF process. That is, molding may be performed in such a manner that a molding material between the semiconductor chips 110 and 120 and the substrate 101 is filled with an under fill, and then a portion of the sidewalls of the semiconductor chips 110 and 120 is covered with the molding material. The under fill filled between the semiconductor chips 110 and 120 and the substrate 101 and the molding material covering a portion of the sidewalls of the semiconductor chips 110 and 120 (i.e., the sidewall region excluding the predetermined heat dissipation trench depth ‘d’ with respect to the sidewall height ‘D’) may be formed of the same material, or may be formed of different materials.

The heat dissipation member 140 may be attached to the upper surfaces and the upper sidewalls of the semiconductor chips 110 and 120 via the TIM 145, and particularly, may have a flat plate shape in which two trenches, including a first trench 141 and a second trench 142 of FIG. 1B, into which upper portions of the first semiconductor chip 110 and the second semiconductor chip 120 are inserted by engagement, are formed on a lower surface. Each of the trenches 141 and 142 may have a shape including a trench depth with which the upper portions of the first semiconductor chip 110 and the second semiconductor chip 120 are engaged, and may have various cross-sectional shapes such as a square or a rectangle depending on an upper shape of each of the first semiconductor chip 110 and the second semiconductor chip 120.

The trench depth may be set up to about 50% of the sidewall height ‘D’ of each of the first semiconductor chip 110 and the second semiconductor chip 120. When the trench depth exceeds 50% with respect to the sidewall height ‘D’, a problem such as undercut and process yield deterioration may occur.

The heat dissipation member 140 may include at least one of a non-metallic material such as carbon and silicon, a metal material such as nickel (Ni), copper, copper alloy, aluminum, aluminum alloy, steel and stainless steel, a metal oxide such as magnesium oxide, alumina and titanium dioxide (TiO₂), and a metal nitride, and a combination thereof.

TIM 145 may include, for example, mineral oil, grease, gap filler putty, phase change gel, phase change material pads, or particle filled epoxy, but is not limited thereto. The TIM 145 may include various materials having excellent thermal conductivity.

The semiconductor package 100 according to an example embodiment of the present disclosure, which is configured as described above, may maintain a size without increasing its overall height by the trench of the heat dissipation member 140 having the depth including the trench depth even though the height of the chips is increased due to a multi-chip structure (e.g., a structure in which the first semiconductor chip 110 and the second semiconductor chip 120 are stacked). Therefore, in the semiconductor package 100 according to an example embodiment of the present disclosure, the first semiconductor chip 110 and the second semiconductor chip 120 may be provided by increasing their respective heights.

Also, in the semiconductor package 100 according to an example embodiment of the present disclosure, heat may be transferred through upper sidewalls of each of the first semiconductor chip 110 and the second semiconductor chip 120 by the heat dissipation member 140 having the trench of the depth including the trench depth ‘d’, whereby heat dissipation efficiency may be improved.

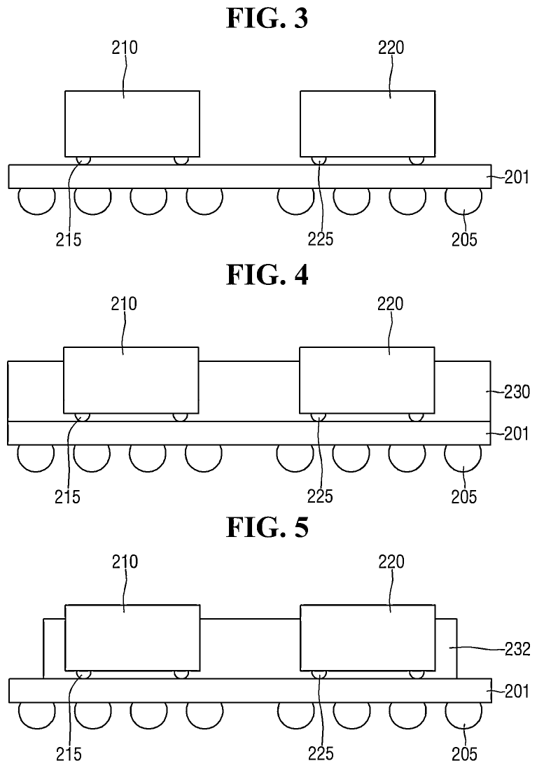

FIG. 2 is a cross-sectional view illustrating a semiconductor package according to an example embodiment of the present disclosure, and FIGS. 3 to 7 are diagrams illustrating a method of manufacturing a semiconductor package according to an example embodiment of the present disclosure. Hereinafter, a semiconductor package 200 and a method of manufacturing the semiconductor package 200 according to an example embodiment of the present disclosure will be described with reference to FIGS. 2 to 7.

Similarly to the semiconductor package 100 according to an example embodiment of the present disclosure, as shown in FIG. 2, the semiconductor package 200 according to an example embodiment of the present disclosure may include a substrate 201, two semiconductor chips including a first semiconductor chip 210 and a second semiconductor chip 220 packaged on an upper surface of the substrate 201, a final molding layer 232 formed to cover (or cover at least a portion of) the upper surface of the substrate 201 and a portion of sidewalls of the semiconductor chips 210 and 220, and a heat dissipation member 240 attached to an upper edge of the substrate 201, an upper portion and sidewalls of the final molding layer 232, and an upper surface and upper sidewalls of the semiconductor chips 210 and 220 with a TIM 245 interposed therebetween. In addition, the semiconductor package 200 according to an example embodiment of the present disclosure may further include bumps 215 and 225 connecting the substrate 201 with the semiconductor chips 210 and 220, respectively, and solder balls 205 attached to a lower surface of the substrate 201.

The semiconductor package 200 according to an example embodiment of the present disclosure may be characterized in that the heat dissipation member 240 is attached, with the TIM 245, to the upper portion and a sidewall of the final molding layer 232 and the upper surface and upper sidewalls of the semiconductor chips 210 and 220.

In detail, as shown in FIG. 2, the heat dissipation member 240 may form two trenches into which an upper portion of each of the first semiconductor chip 210 and the second semiconductor chip 220 is inserted by engagement. Each of the trenches may have a shape of a groove having a depth including a trench depth ‘d’, into which the upper portion of each of the first semiconductor chip 210 and the second semiconductor chip 220 is engaged. The heat dissipation member 240may be mounted on the edge of the upper surface of the substrate 201 by attaching a sidewall having a thickness ‘S’ from the side of the final molding layer 232.

The heat dissipation member 240 may dissipate heat by transferring heat, which is generated in each of the first semiconductor chip 210 and the second semiconductor chip 220, together in a lateral direction as well as an upper direction.

Therefore, the semiconductor package 200 according to an example embodiment of the present disclosure may maintain a size without increasing its overall height by the trench of the heat dissipation member 240, which has a trench depth ‘d’, even though the height of the chip is increased due to the multi-chip structure (e.g., having the structure in which the first semiconductor chip 110 and the second semiconductor chip 120 are stacked). The semiconductor package 200 may dissipate heat by transferring heat in a lateral direction through the sidewall having the thickness ‘S’.

Also, in the semiconductor package 200 according to an example embodiment of the present disclosure, electromagnetic interference (EMI) shielding may be obtained due to a structure in which the heat dissipation member 240 surrounds the first semiconductor chip 210 and the second semiconductor chip 220 in upper and lateral directions.

In the method of manufacturing the semiconductor package 200 according to an example embodiment of the present disclosure, as shown in FIG. 3, the first semiconductor chip 210 and the second semiconductor chip 220 may be respectively packaged on the upper surface of the substrate 201.

Each of the first semiconductor chip 210 and the second semiconductor chip 220 may be packaged on the substrate 201 in a flip-chip bonding method, and may be connected to the substrate 201 using the bumps 215 and 225. Each of the first semiconductor chip 210 and the second semiconductor chip 220 may be packaged on the substrate 201 in a wire bonding method in addition to the flip-chip bonding method, which is an example and not limited thereto.

After each of the first semiconductor chip 210 and the second semiconductor chip 220 is packaged on the upper surface of the substrate 201, as shown in FIG. 4, an initial molding layer 230 may be formed to cover (or cover at least a portion of) the upper surface of the substrate 201 and a portion of the sidewalls of the semiconductor chips 210 and 220.

The initial molding layer 230 may be formed to cover (or cover at least a portion of) the upper surface of the substrate 201 and a portion of the sidewalls of the semiconductor chips 210 and 220. Particularly, the initial molding layer 230 may be formed to cover (or cover at least a portion of) a sidewall region excluding a predetermined heat dissipation trench depth with respect to a sidewall height ‘D’ of the semiconductor chips 210 and 220. The exposed heat dissipation trench depth ‘d’ may be set up to about 50% of the sidewall height ‘D’.

The initial molding layer 230 may be formed by, for example, a MUF process, in which a space between the semiconductor chips 210 and 220 and the substrate 201 is also filled, without a separate process of filling the space between the semiconductor chips 210 and 220 and the substrate 201 with an under fill.

The initial molding layer 230 may be formed by a process other than the MUF process. That is, molding may be performed in such a manner that a molding material between the semiconductor chips 210 and 220 and the substrate 201 is filled with an under fill, and then a process of covering a portion of the sidewalls of the semiconductor chips 210 and 220 with the molding material is performed to expose the heat dissipation trench depth ‘d’. The under fill filled between the semiconductor chips 210 and 220 and the substrate 201 and the molding material covering a portion of the sidewalls of the semiconductor chips 210 and 220 (i.e., the sidewall region excluding the predetermined heat dissipation trench depth with respect to the sidewall height ‘D’) may be formed of the same material, or may be formed of different materials.

After the initial molding layer 230 is formed, as shown in FIG. 5, a removal process of removing a region corresponding to the thickness S may be performed along the edge of the initial molding layer 230.

Laser drilling, wet etching, dry etching, blade, etc., may be used to remove a region corresponding to the thickness S along the edge of the initial molding layer 230.

In this removal process, as shown in FIG. 5, the region corresponding to the thickness S may be removed from the edge of the initial molding layer 230, and an upper surface of the edge of the corresponding substrate 201 may be exposed, whereby the final molding layer 232 is formed.

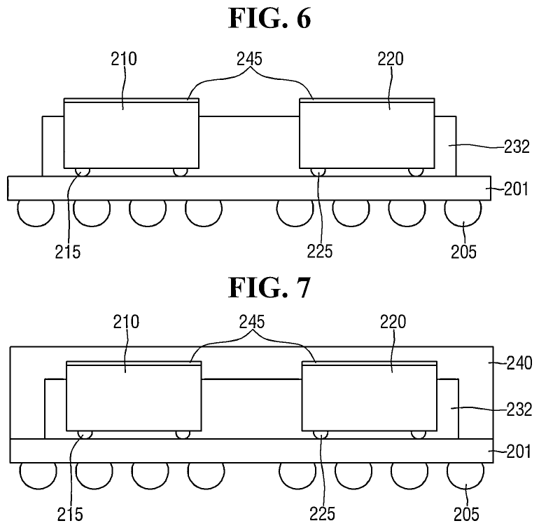

After the final molding layer 232 is formed by the removal process, the TIM 245 may be provided on the upper surface of the semiconductor chips 210 and 220 as shown in FIG. 6. The TIM 245 may be also provided on an upper surface of the edge of the exposed substrate 201 and an outer surface of the final molding layer 232 as well as the upper surface of the semiconductor chips 210 and 220.

The TIM 245 may include, for example, mineral oil, grease, gap filler putty, phase change gel, phase change material pads, or particle filled epoxy, and may include various materials having excellent thermal conductivity.

The TIM 245 may be provided by a method such as coating using a dispenser and coating using a roller.

After the TIM 245 is provided, as shown in FIG. 7, the heat dissipation member 240 (e.g., prepared in advance) may be attached to the upper portion of the edge of the substrate 201, the upper portion and a sidewall of the final molding layer 232 and the upper portions and the upper sidewalls of the semiconductor chips 210 and 220 with the TIM 245 interposed therebetween.

The heat dissipation member 240 may correspond to the upper portion of each of the semiconductor chips 210 and 220 by, for example, injection molding or compression jig, may form two trenches with a depth including the trench depth ‘d’, and may be provided in advance in the form of forming the sidewall having the thickness S.

As described above, the method of manufacturing the semiconductor package 200 according to an example embodiment of the present disclosure may easily manufacture the semiconductor package that dissipates heat by transferring heat of the semiconductor chips 210 and 220 in a lateral direction through the sidewall having the thickness S.

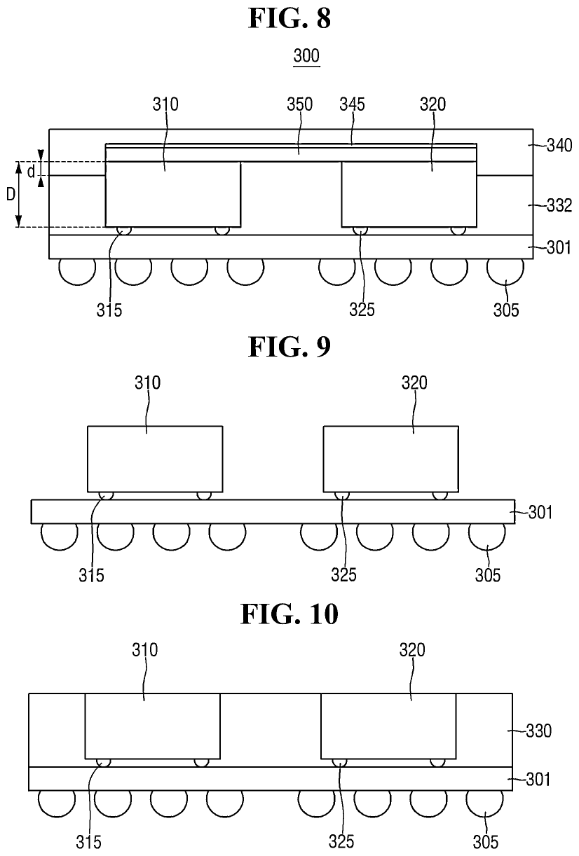

FIG. 8 is a cross-sectional view illustrating a semiconductor package according to an example embodiment of the present disclosure. FIGS. 9 to 13 are diagrams illustrating a method of manufacturing a semiconductor package according to an example embodiment of the present disclosure. Hereinafter, a semiconductor package 300 according to an example embodiment of the present disclosure will be described with reference to FIGS. 8 to 13.

As shown in FIG. 8, the semiconductor package 300 according to an example embodiment of the present disclosure may include a substrate 301, two semiconductor chips including a first semiconductor chip 310 and a second semiconductor chip 320 packaged on an upper surface of the substrate 301, a final molding layer 332 formed to cover (or cover at least a portion of) the upper surface of the substrate 301 and a portion of sidewalls of the semiconductor chips 310 and 320, a dummy heat dissipation plate 350 provided to overlap upper surfaces of the two semiconductor chips 310 and 320, and a heat dissipation member 340 attached to an upper portion of the final molding layer 332, an upper surface and a sidewall of the dummy heat dissipation plate 350 and upper portions of outer sidewalls of the semiconductor chips 310 and 320 with a TIM 345 interposed therebetween. In addition, the semiconductor package 300 according to an example embodiment of the present disclosure may further include bumps 315 and 325 connecting the substrate 301 with the semiconductor chips 310 and 320, respectively, and solder balls 305 attached to a lower surface of the substrate 301.

The semiconductor package 300 according to an example embodiment of the present disclosure may be characterized in that the dummy heat dissipation plate 350 overlapped with the upper surfaces of the semiconductor chips 310 and 320 is further provided to store heat generated while forming thermal equilibrium between the semiconductor chips 310 and 320 and dissipate heat in upper and lateral directions through the heat dissipation member 340.

The semiconductor package 300 according to an example embodiment of the present disclosure may be characterized in that the heat dissipation member 340 has a flat plate shape that forms a trench, into which the dummy heat dissipation plate 350 and an upper portion of each of the first semiconductor chip 310, and the second semiconductor chip 320 are inserted by engagement, at the center on a lower surface thereof. The trench may be formed in the form of a groove having a depth including a thickness of the TIM 345, a thickness of the dummy heat dissipation plate 350 and a trench depth of the semiconductor chips 310 and 320.

Therefore, the semiconductor package 300 according to an example embodiment of the present disclosure may maintain the size without increasing its overall height by the trench of the heat dissipation member 340 even though the height of each of the first semiconductor chip 310 and the second semiconductor chip 320 is increased due to the multi-chip structure and the dummy heat dissipation plate 350 is provided, and may dissipate heat by transferring heat in the lateral direction through the heat dissipation member 340 that contacts the upper sidewalls of the semiconductor chips 310 and 320.

In the method of manufacturing the semiconductor package 300 according to an example embodiment of the present disclosure, as shown in FIG. 9, the first semiconductor chip 310 and the second semiconductor chip 320 may be respectively packaged on the upper surface of the substrate 301.

Each of the first semiconductor chip 310 and the second semiconductor chip 320 may be packaged on the substrate 301 in a flip-chip bonding method, and may be connected to the substrate 201 using the bumps 315 and 325. Each of the first semiconductor chip 310 and the second semiconductor chip 320 may be also packaged on the substrate 301 in a wire bonding method in addition to the flip-chip bonding method, which is an example and not limited thereto.

After each of the first semiconductor chip 310 and the second semiconductor chip 320 are packaged on the upper surface of the substrate 301, as shown in FIG. 10, an initial molding layer 330, which contacts the upper surface of the substrate 301 and all of the sidewalls of the semiconductor chips 310 and 320, is provided on the semiconductor package 300.

The initial molding layer 330 may be formed by, for example, a MUF)process, in which a space between the semiconductor chips 310 and 320 and the substrate 301 is also filled, without a separate process of filling the space between the semiconductor chips 310 and 320 and the substrate 301 with an under fill. The initial molding layer 330 may be formed by a process other than the MUF process. That is, a molding material between the semiconductor chips 310 and 320 and the substrate 301 may be filled with an under fill, and then a process of covering the sidewalls of the semiconductor chips 310 and 320 with the molding material may be performed.

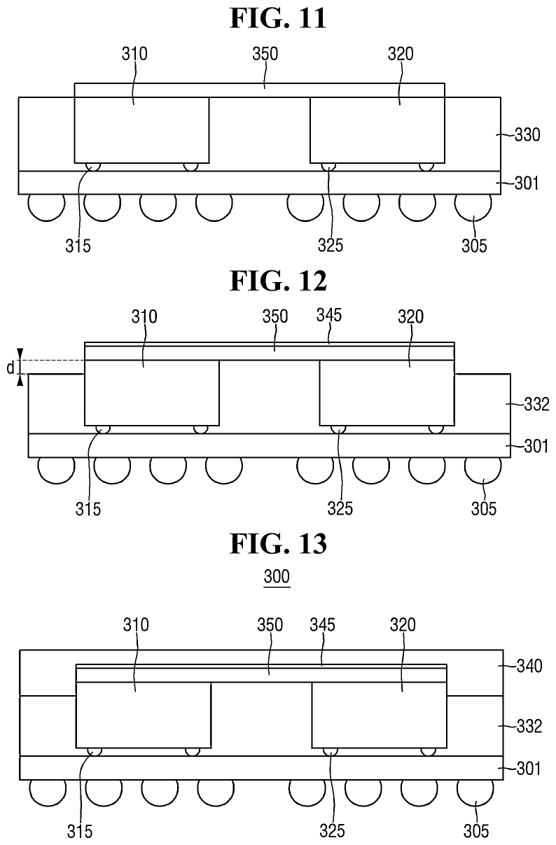

After the initial molding layer 330 is formed, as shown in FIG. 11, the dummy heat dissipation plate 350 may be mounted on the exposed upper surfaces of the semiconductor chips 310 and 320 as shown in FIG. 11.

The dummy heat dissipation plate 350 may have a plate shape and may be formed of the same material as that of the heat dissipation member 340. For example, the dummy heat dissipation plate 350 may include at least one of a non-metallic material such as carbon and silicon, a metal material such as nickel (Ni), copper, copper alloy, aluminum, aluminum alloy, steel and stainless steel, a metal oxide such as magnesium oxide, alumina and titanium dioxide (TiO₂), and a metal nitride, and a combination thereof.

The dummy heat dissipation plate 350 may be bonded to the upper surface of each of the first semiconductor chip 310 and the second semiconductor chip 320 using the TIM.

Since the dummy heat dissipation plate 350 is bonded to the upper surface of each of the first semiconductor chip 310 and the second semiconductor chip 320 to overlap the corresponding upper surface, a transfer path of heat generated from the first semiconductor chip 310 and the second semiconductor chip 320 may be widened to dissipate heat.

After the dummy heat dissipation plate 350 is mounted, as shown in FIG. 12, a removal process of removing a corresponding region with a predetermined heat dissipation trench depth (e.g., corresponding to a trench of a heat dissipation member 340) along an outer edge region of the initial molding layer 330 may be performed.

The final molding layer 332 may be formed by removing the region of the predetermined heat dissipation trench depth from the outer edge of the initial molding layer 330, as shown in FIG. 12, through the removal process, and the outer upper sidewalls of each of the first semiconductor chip 310 and the second semiconductor chip 320 may be exposed to an amount corresponding to the heat dissipation trench depth ‘d’. The exposed heat dissipation trench depth may be set up to about 50% of the sidewall height ‘D’ of each of the first semiconductor chip 310 and the second semiconductor chip 320.

After the final molding layer 332 is formed by the removal process, the TIM 345 may be provided on the upper surface of the dummy heat dissipation plate 350 as shown in FIG. 12. The TIM 345 may include, for example, mineral oil, grease, gap filler putty, phase change gel, phase change material pads, or particle filled epoxy, and may include various materials having excellent thermal conductivity.

The TIM 345 may be provided by a method such as coating using a dispenser and coating using a roller.

After the TIM 345 is provided, as shown in FIG. 13, the heat dissipation member 340 (e.g., prepared in advance) may be attached to the upper surface and a sidewall of the dummy heat dissipation plate 350, an upper edge of the final molding layer 332 and the upper portion of the outer sidewalls of each of the semiconductor chips 310 and 320 with the TIM 345 interposed therebetween.

The heat dissipation member 340 may be configured to correspond to the dummy heat dissipation plate 350 by, for example, injection molding or compression jig, and may be provided in advance in the form of a plate shape having a trench of a groove shape having a depth including a thickness of the TIM 345, a thickness of the dummy heat dissipation plate 350, and the trench depth of the semiconductor chips 310 and 320.

As described above, the method of manufacturing the semiconductor package 300 according to an example embodiment of the present disclosure may easily manufacture the semiconductor package 300 that transfers heat generated while forming thermal equilibrium between the semiconductor chips 310 and 320 through the dummy heat dissipation plate 350 and dissipates heat in a lateral direction through the heat dissipation member 340.

Particularly, in the method of manufacturing the semiconductor package 300 according to an example embodiment of the present disclosure, even though the height of each of the first semiconductor chip 310 and the second semiconductor chip 320 is increased and the dummy heat dissipation plate 350 is provided, the semiconductor package 300, which may maintain the size without increasing its overall height by the trench of the heat dissipation member 340, may be easily manufactured.

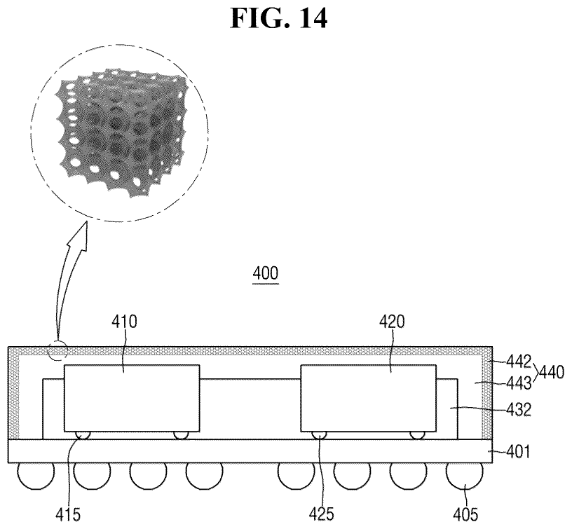

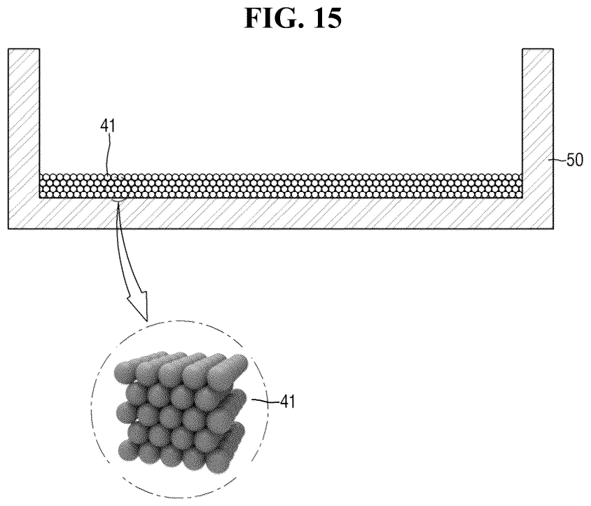

Hereinafter, a semiconductor package 400 according to an example embodiment of the present disclosure will be described with reference to FIGS. 14 to 20. FIG. 14 is a cross-sectional view illustrating a semiconductor package according to an example embodiment of the present disclosure. FIGS. 15 to 20 are diagrams illustrating a method of manufacturing a semiconductor package according to an example embodiment of the present disclosure. Hereinafter, a semiconductor package 400 according to an example embodiment of the present disclosure will be described with reference to FIGS. 14 to 20.

Similarly to the semiconductor package 200 according to an example embodiment of the present disclosure, as shown in FIG. 14, the semiconductor package 400 according to an example embodiment of the present disclosure may include a substrate 401, two semiconductor chips, including a first semiconductor chip 410 and a second semiconductor chip 420 packaged on an upper surface of the substrate 401, a final molding layer 432 formed to cover (or cover at least a portion of) the upper surface of the substrate 401 and a portion of sidewalls of the semiconductor chips 410 and 420, and a heat dissipation member 440 attached to an upper edge of the substrate 401, an upper portion and a sidewall of the final molding layer 432, and an upper portion and upper sidewalls of the semiconductor chips 410 and 420 with a TIM interposed therebetween. In addition, the semiconductor package 400 according to an example embodiment of the present disclosure may further include bumps 415 and 425 connecting the substrate 401 with the semiconductor chips 410 and 420, respectively, and solder balls 405 attached to a lower surface of the substrate 401.

The semiconductor package 400 according to an example embodiment of the present disclosure may be characterized in that the heat dissipation member 440 includes a heat dissipation base portion 443 and a heat dissipation portion 442 including a porous pattern of a plurality of pores three-dimensionally connected to one another (e.g., to pass through one another) on an upper surface of the heat dissipation base portion 443, and the heat dissipation member 440 is attached to the upper portion and the sidewall of the final molding layer 432 and the upper surface and upper sidewalls of the semiconductor chips 410 and 420 with the TIM interposed therebetween.

In detail, the heat dissipation base portion 443 may include a polymer and a thermally conductive filler.

The polymer may be a polymer having an insulating property, and may include, for example, polypropylene, acrylonitrile butadiene styrene, polycarbonate, nylon, polyphenylene sulfide, polythiophene, polyetheretherketone, and the like. The polymer component is not limited to the above-described materials, but any polymer having an insulating property may be used.

The thermally conductive filler may be a ceramic component or a metal component, which may be selectively added to form a thermal conduction path on a grain boundary surface between polymer particles, and the ceramic component may include at least one or a composite of, for example, boron nitride, aluminum nitride, magnesium oxide, aluminum oxide, silicon carbide and silicon nitride, and the metal component may include at least one or a composite of copper, aluminum, gold and silver.

The heat dissipation base portion 443 configured as above may be electrically insulated by the polymer component, and may serve to transfer heat transferred from the semiconductor chips 410 and 420 to a heat dissipation portion 442 by the thermally conductive filler.

As shown in FIG. 14, the heat dissipation portion 442 may include a porous structure including a plurality of pores three-dimensionally connected to one another (e.g., to pass through one another), and the porous structure may be formed of, for example, at least one of a non-metallic material such as carbon and silicon, a metal material such as nickel (Ni), copper (Cu) and aluminum, a metal oxide such as magnesium oxide, alumina, and titanium dioxide (TiO₂) or a metal nitride, and a combination thereof.

The pores may have a diameter of several tens of micrometers to a diameter of several millimeters, and may be three-dimensionally connected to one another by forming a plurality of connection paths with other pores. As shown in FIG. 15, the connection path between the pores may be formed by surface junction between a plurality of beads 41, which will be described later, and surface junction portions between the beads 41 formed in a closest packing structure formed by the plurality of beads 41 may be formed as a plurality of connection paths.

Since the heat dissipation portion 442 is a structure in which a plurality of pores are three-dimensionally connected to one another, the heat dissipation portion 442 may increase a heat dissipation amount per unit area by maximizing a porous ratio, thereby improving heat dissipation efficiency.

As shown in FIG. 14, the heat dissipation member 440 configured as described above may include two trenches (e.g., trenches 498 and 499 of FIG. 18) engaged and inserted into upper portions of the first semiconductor chip 410 and the second semiconductor chip 420 therebelow. Each of the trenches 498 and 499 may be in the form a groove having a depth including a trench depth with which an upper portion of each of the first semiconductor chip 410 and the second semiconductor chip 420 is engaged, and may be mounted on an edge of the upper surface of the substrate 401.

The heat dissipation member 440 may transfer heat generated from each of the first semiconductor chip 210 and the second semiconductor chip 220 in a lateral direction as well as an upper direction through the heat dissipation base portion 443, such that heat dissipation efficiency through the heat dissipation portion 442 may be maximized.

Therefore, the semiconductor package 400 according to an example embodiment of the present disclosure may maintain a size without increasing its overall height by the trench of the heat dissipation member 440, which has a trench depth ‘d’ even though the height of the chip is increased due to the multi-chip structure having the structure in which the first semiconductor chip 410 and the second semiconductor chip 420 are stacked, may dissipate heat in a lateral direction, and may maximize heat dissipation efficiency through the heat dissipation portion 442.

In the method of manufacturing the semiconductor package 400 according to an example embodiment of the present disclosure, as shown in FIG. 15, in order to manufacture the heat dissipation portion 442 constituting the heat dissipation member 440, the bead 41 may be immersed in an inner groove of a mold 50 corresponding to a size of the heat dissipation member 440 together with ethanol solution and precipitated in a stacked structure at a temperature below a room temperature.

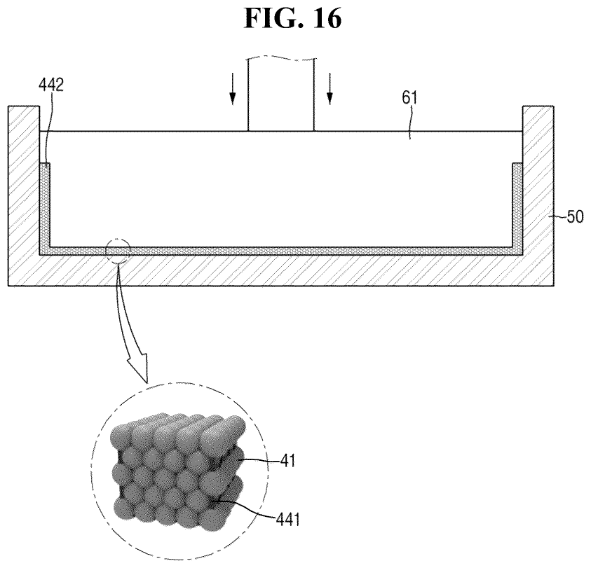

Afterwards, as shown in FIG. 16, a plurality of beads 41 precipitated by pressing a first jig 61 into the inner groove of the mold 50 may be arranged in the form of the heat dissipation portion 442. The first jig 61 may be in the form of a piston having a rectangular lower surface corresponding to the shape of the heat dissipation portion 442.

As slow-cooling drying or freeze-drying is performed in a state that the plurality of beads 41 are arranged as described above, the plurality of beads 41 may form a closest packed structure such as a hexagonal closest packed structure or a cubic closest packed structure.

After the ethanol is completely evaporated, in order to increase a contact area between the beads 41 in the stacked structure of the beads 41, a pressurizing and heating process may be performed for the stacked structure of the beads 41.

In the stacked structure of the beads 41 by the pressurizing and heating process, the plurality of beads 41 may be closely adhered to each other to increase the contact area between the beads 41.

With respect to the stacked structure of the beads 41 that become dense, a heat dissipation portion precursor 441 may be injected into the stacked structure of the beads 41 and heated as shown in FIG. 16.

The heat dissipation portion precursor 441 may be selected depending on the material of the porous structure described above, and thus may be variously prepared depending on a material including at least one of a non-metallic material such as carbon and silicon, a metal material such as nickel (Ni), copper and aluminum, a metal oxide such as magnesium oxide, alumina and titanium dioxide (TiO₂), and a metal nitride. For example, when the porous structure is formed of a carbon material, the heat dissipation portion precursor 441 may be, for example, Resorcinol.

As shown in FIG. 16, the heat dissipation portion precursor 441 prepared as described above may be put into the stacked structure of the beads 41 and then heated to perform a gelation process. In order to smoothly insert the heat dissipation portion precursor 441, the insertion of the heat dissipation portion precursor 441 for carbon may be performed by compression using the first jig 61.

Afterwards, a carbonization process of heating the stack structure of the beads 41 including the heat dissipation portion precursor 441 for a predetermined time in the atmosphere of nitrogen may be performed.

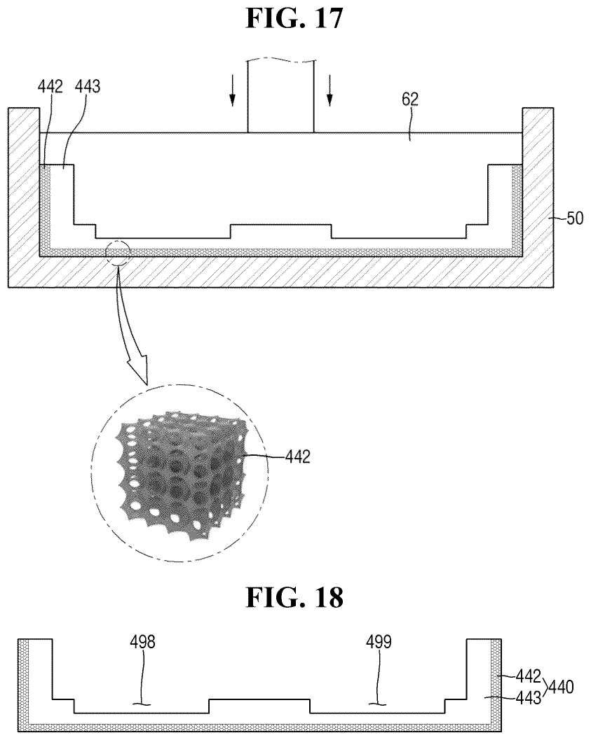

By the carbonization process, as shown in FIG. 17, the beads 41 may be dissipated and the heat dissipation portion precursor 441 may be carbonized, such that the heat dissipation portion 442 of the porous structure having a plurality of pores three-dimensionally connected through the plurality of connection paths may be formed.

After the heat dissipation portion 442 of the porous structure is formed as described above, a mixture including a polymer and a thermally conductive filler may be filled in the heat dissipation portion 442, and may be compressed and hardened through a second jig 62, as shown in FIG. 17.

A lower surface of the second jig 62 may have a shape corresponding to a shape of an inner surface of the heat dissipation base portion 443, and the second jig 62 may compress the mixture to form coupling with the heat dissipation portion 442, thereby hardening the mixture.

After the mixture is hardened, the second jig 62 may be removed and separated from the mold 50, such that the heat dissipation member 440 including the heat dissipation base portion 443 and the heat dissipation portion 442 may be obtained as shown in FIG. 18.

The heat dissipation member 440 may form two trenches 498 and 499 engaged and inserted into the upper portions of the first semiconductor chip 410 and the second semiconductor chip 420 on the inner surface of the heat dissipation base portion 443. Each of the trenches 498 and 499 may have a rectangular groove shape having a depth including a trench depth with which the upper portions of the first semiconductor chip 410 and the second semiconductor chip 420 are engaged.

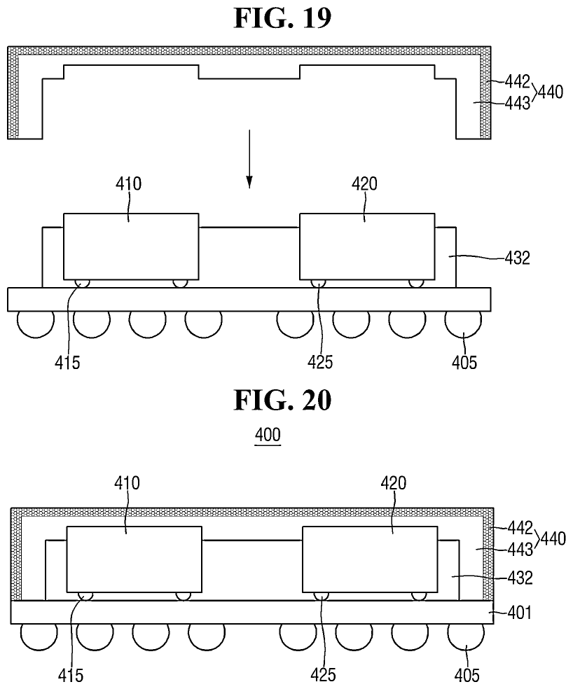

As shown in FIG. 19, the heat dissipation member 440 obtained as described above may be engaged and attached to the semiconductor chips 410 and 420 and the final molding layer 432, which are provided on the upper surface of the substrate 401. The inner surface of the heat dissipation base portion 443 of the heat dissipation member 440 may be engaged and attached to the semiconductor chips 410 and 420 and the final molding layer 432 in a state in which the TIM is provided in advance.

Therefore, as shown in FIG. 20, the semiconductor package 400 according to an example embodiment of the present disclosure may be formed, in which the heat dissipation member 440 is attached to the upper edge of the substrate 401, the upper portion and the sidewall of the final molding layer 432, the upper portion and the upper sidewalls of the semiconductor chips 410 and 420 with the TIM interposed therebetween.

The method of manufacturing the semiconductor package 400 according to an example embodiment of the present disclosure may easily manufacture the heat dissipation member 440 comprised of the heat dissipation base portion 443 and the heat dissipation portion 442, may maintain the size without increasing the overall height of the package by the trench of the heat dissipation member 440, and may obtain a semiconductor package that dissipates heat in the lateral direction and maximizes heat dissipation efficiency through the heat dissipation portion 442.

Example embodiments may provide a heat dissipation member with a trench in order to maintain a size while accommodating a semiconductor chip with increased thickness. The heat dissipation member may be disposed on the sidewall of the semiconductor chip to have a depth of less than about 50% of the height of the sidewall of the semiconductor chip, and the heat dissipation member may be disposed to contact the sidewall of the semiconductor chip. The structure in some embodiments may be limited to a package including two semiconductor chips and additionally equipped with a dummy heat sink. Thus, example embodiments may increase the heat dissipation efficiency of the semiconductor chip.

Each of the embodiments provided in the above description is not excluded from being associated with one or more features of another example or another embodiment also provided herein or not provided herein but consistent with the disclosure.

Although example embodiments of the present disclosure have been described with reference to the accompanying drawings, it will be apparent to those skilled in the art that the present disclosure can be implemented in various forms without being limited to the above-described embodiments and can be embodied in other specific forms without departing from the spirit and essential characteristics of the present disclosure. Thus, the above example embodiments are to be considered in all respects as illustrative and not restrictive.

What is claimed is:

1. A semiconductor package comprising:
a substrate;
at least one semiconductor chip provided on an upper surface of the substrate;
a molding layer provided on a portion of a sidewall of the at least one semiconductor chip; and
a heat dissipation member comprising at least one trench that contacts an upper surface of the at least one semiconductor chip and another portion of the sidewall of the at least one semiconductor chip.

2. The semiconductor package of claim 1, further comprising:
bumps connecting the substrate with the at least one semiconductor chip; and
solder balls attached to a lower surface of the substrate.

3. The semiconductor package of claim 1, wherein the at least one trench has a depth equal to or less than 50% of a height of the sidewall of the at least one semiconductor chip.

4. The semiconductor package of claim 1, further comprising a thermal interface material (TIM) provided between the upper surface of the at least one semiconductor chip and the at least one trench of the heat dissipation member,
wherein the TIM attaches the upper surface of the at least one semiconductor chip to the heat dissipation member.

5. The semiconductor package of claim 1, wherein the heat dissipation member has a flat plate shape.

6. The semiconductor package of claim 1, wherein the heat dissipation member is provided on an upper portion the molding layer, and
wherein the heat dissipation member is provided on an edge of the upper surface of the substrate.

7. The semiconductor package of claim 1, further comprising a dummy heat dissipation plate provided between a thermal interface material (TIM) and the upper surface of the at least one semiconductor chip.

8. The semiconductor package of claim 1, wherein the heat dissipation member comprises a heat dissipation base portion and a porous patterned portion, and
wherein the porous patterned portion comprises a plurality of pores three-dimensionally connected on an upper portion of the heat dissipation base portion.

9. The semiconductor package of claim 8, wherein the heat dissipation base portion comprises a polymer and a thermally conductive filler, and
wherein the porous patterned portion comprises at least one of a non-metallic material, a metal material, a metal oxide, or a metal nitride.

10. A semiconductor package comprising:
a substrate;
at least two semiconductor chips provided on an upper surface of the substrate;
a molding layer provided on the upper surface of the substrate and first portions of sidewalls of the at least two semiconductor chips; and
a heat dissipation member comprising:
a first trench engaged with an upper portion and upper sidewalls of a first semiconductor chip of the at least two semiconductor chips, and
a second trench engaged with an upper portion and upper sidewalls of a second semiconductor chip of the at least two semiconductor chips,
wherein the heat dissipation member is provided on an upper edge of the substrate, an upper portion of the molding layer, a sidewall of the molding layer, an upper surface of each of the at least two semiconductor chips, and second portions of the sidewalls of the at least two semiconductor chips.

11. The semiconductor package of claim 10, further comprising:
bumps connecting the substrate with the at least two semiconductor chips; and
solder balls attached to a lower surface of the substrate.

12. The semiconductor package of claim 10, wherein each of the first trench and the second trench is formed to have a depth equal to or less than 50% of a height of the sidewalls of the at least two semiconductor chips.

13. The semiconductor package of claim 10, further comprising a thermal interface material (TIM) provided between the upper portions of the at least two semiconductor chips and the heat dissipation member,
wherein the TIM attaches the upper portions of the at least two semiconductor chips to the heat dissipation member.

14. The semiconductor package of claim 10, wherein the at least two semiconductor chips form a multi-chip comprising a stacked structure, and
wherein the at least two semiconductor chips comprise a memory device or a micro-controller device.

15. The semiconductor package of claim 10, wherein the heat dissipation member comprises a heat dissipation base portion and a porous patterned portion, and
wherein the porous patterned portion comprises a plurality of pores three-dimensionally connected an upper portion of the heat dissipation base portion.

16. The semiconductor package of claim 15, wherein the heat dissipation base portion comprises a polymer and a thermally conductive filler, and
wherein the porous patterned portion comprises at least one of a non-metallic material, a metal material, a metal oxide, or a metal nitride.

17. A semiconductor package comprising:
a substrate;
at least two semiconductor chips provided on an upper surface of the substrate;
a molding layer provided on the upper surface of the substrate and a portion of sidewalls of the at least two semiconductor chips;
a dummy heat dissipation plate provided on an upper surface of each of the at least two semiconductor chips;
a thermal interface material (TIM) provided on the dummy heat dissipation plate; and
a heat dissipation member provided on upper sidewalls of the at least two semiconductor chips, at least a portion of the dummy heat dissipation plate and at least a portion of the TIM,
wherein the heat dissipation member contacts at least one of the upper sidewalls of the at least two semiconductor chips.

18. The semiconductor package of claim 17, wherein the dummy heat dissipation plate contacts an upper surface of the molding layer between the at least two semiconductor chips.

19. The semiconductor package of claim 17, wherein the dummy heat dissipation plate has a plate shape, and
wherein the dummy heat dissipation plate is formed of a material that is the same as a material of the heat dissipation member.

20. The semiconductor package of claim 17, wherein a sidewall of the dummy heat dissipation plate contacts the molding layer.
